(19) United States
(12) Patent Application Publication
(10) Pub. No.: US 2011/0000535 A1
(43) Pub. Date: Jan. 6, 2011

(54) Spanish shingles with photovoltaic cells, method of producing and method of installation

(75) Inventor: Neil James Davidson, Redondo Beach, CA (US)

Correspondence Address: F. EUGENE LOGAN;SUITE 201, 202 FASHION LAND, TUSTIN, CA, 92780, US

(73) Assignee: SOUND SOLAR SOLUTIONS LLC, ORANGE, CA (US)

(21) Appl. No.: 12/459,513

(22) Filed: Jul. 2, 2009

(51) Int. Cl. H01L 31/00; E04D 13/18; E04D 1/00; H05K 3/00

(52) U.S. Cl. 136/256; 52/173.3; 52/518; 29/829

(57) ABSTRACT

A photovoltaic shingle having a photovoltaic assembly with a photovoltaic cell or cells. The substrate has an outward face and an inward face and a profile having a plurality of traverse parallel ridges with each ridge separated from the next ridge by a traverse parallel trough. The substrate facilitates vertical and horizontal nesting and alignment. The photovoltaic cell substantially spans the outward face except for a portion thereof that is intended to be overlapped by another similar shingle. The substrate can have two tiers or more, each tier being separated by an integral riser that creates the appearance of two rows or more of shingles. The substrate can be produced from recyclable plastic. The shingles have a translucent color enhancing means for imparting an uniform color and can be produced in many colors and shapes. The shingle is attached directly to a building or roof structure without an intermediary support or framing structure therebetween.

### BACKGROUND OF THE INVENTION

1. Field of the Invention

This invention is directed to the conversion of solar radiation directly into electrical power by photovoltaic methods.

2. Related Background Art

In view of the increased cost of petroleum derived fuels and the pollution produced by the combustion of such fuels and other carbon containing fuels, and the incentives provided by governments for clean sources of energy, the direct conversion of solar radiation into electric power is both desirable and needed.

The industry has recognized that since the roofs of buildings usually receive unobstructed solar radiation that roofs are a good location for installing photovoltaic devices.

U.S. Pat. No. 6,541,693 discloses a solar cell module having a finished form with a reinforcing sheet that is initially flat but then shaped into a slightly corrugated configuration as shown in FIGS. 8A and 8B. The reinforcing sheet is worked by bending, without regard to whether or not the photovoltaic device cell block lay there, to form a slightly corrugated configuration having a top flange and a bottom flange. The flanges are apparently for connection to a frame or a support structure.

Another slightly corrugated roofing material integral type solar cell module is shown in FIG. 11. This solar cell module has side flanges that are also apparently for connection to a frame or a support structure.

Another solar cell module characterized in that it has been bent to form a hill and a valley is shown in FIGS. 10A and 10B. The solar cell module has a top flange and a bottom flange that are apparently for connection to a frame or a support structure.

US Pub. No. 2008/0098672 discloses solar panels that substantially conform to curved surfaces, including S-shaped and M-shaped panels. Some of the solar panels are shown to cover only a portion of the roofing tile. Some of the solar panels are shown on only a few of the roofing tiles on the roof. Vinyl and foam modules can be encapsulated in UV stabilized polymers and bonded and stitched to a cushioned backing material. Other curved surface tiles have a solar panel that covers about half of the tile's convex surface and none of the tile's concave surfaces are shown in FIGS. 7-9.

U.S. Pub. No. 2008/0135094 discloses a thin film solar cell or photovoltaic roof tile in FIG. 7 having a curved or Spanish style-like shape with a thin film solar cell on its curved convex surface. Only a portion of the tile surface is covered by the solar cell. The tiles may have a plurality of fins that depend from the underside of the tile that function as a heat sink to remove heat absorbed by the photovoltaic cell that is not converted to electricity.

U.S. Pat. No. 5,575,861 discloses an arcuate photovoltaic shingle system having a substrate with a series of independent and spaced apart photovoltaic cells separated by gaps and arranged on the lower half of a single strip of roofing material in FIGS. 8-15.

U.S. Pat. No. 4,946,512 discloses a solar energy collector device that simultaneously produces electrical and thermal energy. FIGS. 6 and 7 show an arcuate or Spanish style-like shaped tile assembly mounted on a roof. Each individual tile 10a is produced from metal hot melt and granular or fibrous mix into a block as seen. A solar energy battery rimmed with a plastic heat insulator is affixed to each tile.

WIPO Pub. No. WO/2007/013115 discloses a tile roof covering system that absorbs and/or converts solar energy striking a shingled roof. A first embodiment shown in FIGS. 1-4 and 6, comprises arcuate roofing tiles having a hollow semicircular portion through which is circulated a diathermy or heat transfer fluid. The fluid is circulated to a boiler or heat exchanger which transfer heat to another fluid that is pumped into other means for heating the house below the roof.

A second embodiment shown in FIG. 5, comprises a plurality of spaced apart flat photovoltaic cells arranged on the outer flat surfaces of a semidecagonal tile.

U.S. Pat. No. 5,651,226 discloses tile modules having more than one tile S-shape unit vertically per shingle as shown in FIG. 4A, or more than one tile S-shape unit horizontally per shingle as shown in FIG. 4B. Various designs for interlocking the tiles also are disclosed. The tile modules, together with the underlying surface, form an airspace therebetween such that a plurality of interfitting tiles installed upon the surface will form ducts that can conduct a fluid, such as air, heated by the absorbed solar energy to a location at which it can be dissipated.

U.S. D396,118 discloses the design of a tile roofing sheet having more than one S-shape portion horizontally per roofing sheet.

U.S. D374,095 and U.S. D273,233 show designs of arcuate roofing tiles.

U.S. D285,829 shows a design of a solar tile for heating of a flow through heat transfer fluid.

U.S. Pat. No. 6,875,914 discloses a photovoltaic roofing system based upon the use of a plurality of pairs of photovoltaic shingle materials that are configured to allow front surface connection and which do not require penetration of a roof deck.

US Pub. No. 2008/0053519 discloses various thin flexible photovoltaic cells that are integrated with residential structures comprising roofing tiles, a substrate, a back electrical contact layer, a semiconductor p-n junction, and a conductive grid line. The photovoltaic cells are encapsulated, and chemically inert and UV resistant.

US Pub. No. 2007/0089780 mentions physical vapor deposition (PVD) methods and chemical vapor depositions (CVD) methods and materials in the production of solar cells.

U.S. Pat. No. 4,359,043 discloses a roofing member for transferring solar energy to a heat-carrying fluid within a M-shaped tile.

U.S. Pat. No. 4,299,201 discloses a highly efficient solar focusing means for focusing solar rays onto a pipe containing a heat transfer fluid. Focusing means in a semicylindrical or arcuate shape are said to have the appearance of a Spanish-style roof. Instead of a pipe containing a heat transfer fluid, the upper surface of such pipes may have semiconductors converting solar rays to electricity.

US Pub. No. 2005/0279400 disclose electric tile modules having both a photovoltaic element and a thermovoltaic element for generating electrical power and a diagram for electrically connecting the tile modules.

US Pub. No. 2006/0225778 discloses a photovoltaic module having two different photovoltaic materials specifically for absorption of two different wavelengths.

Arcuate roofing tiles designs are disclosed in U.S. design patents D574,493 for a S-shaped roofing tile, and D479,885 and D458,392 for arcuate roofing tiles with cloaked vent.

### SUMMARY OF THE INVENTION

While the roofs of industrial buildings have been used for many solar energy devices, it would be desirable for such solar devices to be cheaper to manufacture and install, more efficient in the conversion to electrical energy and the transmission of the electricity, to be more durable, and to be aesthetically pleasing so that such solar devices would be acceptable on residential homes without the need for shielding such devices from view.

It would also be desirable if such solar devices would be made from, at least in part, recyclable materials. It would be desirable too for a shingle to be made largely of plastic so that it would weigh less thereby allowing a single shingle to be larger and cover more area on a roof.

The larger shingle can be made to appear to contain more than one row of shingles, and/or more than one column of shingles. Such a shingle would take less time to install than smaller shingles and would reduce installation cost.

This invention seeks to provide such solar devices with at least some of these desired characteristics that can be produced in a variety of styles, shapes and colors for residential as well as industrial use.

In this invention, a photovoltaic shingle having a photovoltaic assembly with a photovoltaic cell or cells, is affixed to and conformed to a substrate. The substrate has an outward face and an inward face and a profile having a plurality of traverse parallel ridges with each ridge separated from the next ridge by a traverse parallel trough. The ridges and troughs extend the width of the substrate from the bottom end to the top end thereof. The substrate facilitates vertical and horizontal nesting and alignment.

In one embodiment of this invention, the photovoltaic cell spans the outward face except for a portion thereof that is intended to be overlapped by another similar shingle, and except for a narrow peripheral band around a peripheral area that is not overlapped by another similar shingle. In a further embodiment the narrow peripheral band is no greater than about one inch (25 mm) in width. In a still further embodiment the narrow peripheral band is about 0.5 inches (13 mm) in width.

In another embodiment of this invention, the shingles can have a transparent or translucent color enhancing means that imparts an uniform color to substantially the entire exposed portions of the shingles when installed on a roof.

The traverse parallel ridges and troughs of the substrate can be semicylindrical or semiconical or any other repetitive pattern having ridges and troughs. The traverse parallel ridges and troughs can comprise berms or rims for enabling a snug overlap of the shingles.

In yet another embodiment of this invention, the substrate can have two tiers or more, each separated by an integral riser that creates the appearance of two rows or more of shingles.

The substrate can be produced from recyclable plastic to reduce shingle weight or permit larger shingles for a given weight while reducing the amount of discarded plastic material sent to dump sites.

The shingles of this invention can be produced in many colors and shapes thereby allowing extensive architectural creativity.

The shingles of this invention can be installed on a building structure or roof structure by merely inserting fasteners, e.g. screws, nails or bolts, through fastener receiving means, e.g. apertures, in the substrate near the top end thereof to attach the shingle directly to a building structure or roof structure without a support or framing structure for spacing the shingle above and away from the roof structure except for an optional intermediate layer comprising a moisture barrier material, or a thermal insulation material, or a thermal insulation/moisture barrier material.

In one embodiment the substrate is free of means for attaching the photovoltaic shingle to a support or framing structure for spacing the shingle away from the building structure except for an optional intermediate layer comprising a moisture barrier material, or a thermal insulation material, or a thermal insulation/moisture barrier material.

In one embodiment the optional intermediate layer is no greater than about 0.6 inches (15 mm) and usually will be no greater than about 0.1 inches (3 mm).

In another embodiment the photovoltaic cell is a thin film photovoltaic cell. In still another embodiment the photovoltaic cell is a cadmium-telluride photovoltaic cell. In yet another embodiment the photovoltaic cell is a thin film cadmium-telluride photovoltaic cell. In a further embodiment the cadmium-telluride photovoltaic cell comprises carbon nanostructures for enhancing electrical conductivity. In still a further embodiment the carbon nanostructures are carbon nanotubes.

In one embodiment the photovoltaic cell covers at least about 85% of the lower area of the outward face of the substrate that is not intended to be overlapped by a photovoltaic cell of another shingle having the same profile. In a further embodiment the photovoltaic cell covers at least about 90% of the lower area of the outward face of the substrate that is not intended to be overlapped by a photovoltaic cell of another shingle having the same profile. In a still further embodiment the photovoltaic cell covers at least about 95% of the lower area of the outward face of the substrate that is not intended to be overlapped by a photovoltaic cell of another shingle having the same profile. In another embodiment the photovoltaic cell covers approximately all of the lower area of the outward face of the substrate that is not intended to be overlapped by another shingle.

In one embodiment the lower area of the outward face is at least about 67% of the outward area. In a further embodiment the lower area of the outward face is at least about 75% of the outward area. In a still further embodiment the lower area of the outward face is at least about 85% of the outward area.

In one embodiment the photovoltaic cell assembly further comprises a plurality of tiered photovoltaic cell assemblies oriented parallel to the bottom end of the substrate, and wherein each tiered photovoltaic cell assembly has a photovoltaic cell.

In one embodiment the photovoltaic shingle further comprises means for removing electrical energy produced by the photovoltaic cell assembly.

In one embodiment the photovoltaic cell assembly comprises anode means and cathode means for removing electrical energy from, and produced by, the photovoltaic shingle. In a further embodiment, when the photovoltaic shingle is attached to a structure, the anode means and the cathode means can not be seen from the outside because of the color enhancing layer or layers in the thin film photovoltaic cells and/or the encapsulating layer. In a further embodiment the photovoltaic shingle comprises electrical connectors for connecting to the anode means and cathode means and for transmitting the electrical energy therefrom to an DC-to-AC inverter.

In another embodiment, when the photovoltaic shingle is attached to a building structure or roof structure, the anode means and the cathode means and the electrical connectors can not be seen from the outside.

In one embodiment of this invention the photovoltaic shingle the substrate has first interlocking mechanical coupling means proximate the left end of the substrate and second interlocking mechanical coupling means proximate the right end of the substrate. The first interlocking mechanical coupling means can be coupled to second interlocking mechanical coupling means of another substrate having the shape and profile. The second interlocking mechanical coupling means can be coupled to the first interlocking mechanical coupling means of another substrate having the same shape and profile. In a further embodiment the electrical connectors have first electrical coupling means proximate the left end of the substrate and second electrical coupling means proximate the right end of the substrate. The first electrical coupling means can be coupled to second electrical coupling means of another substrate having the same shape and profile, and wherein the second electrical coupling means can be coupled to first electrical coupling means of another substrate having the same shape and profile.

In a still further embodiment the first electrical coupling means is embedded in the first interlocking mechanical coupling means, and the second electrical coupling means is embedded in the second interlocking mechanical coupling means.

In one embodiment the photovoltaic cell assembly comprises encapsulating means for sealing the photovoltaic cell on and to the substrate so that, when the photovoltaic shingle is attached to the structure, rain will be prevented from penetrating the photovoltaic cell assembly and damaging the photovoltaic cell.

In one embodiment the substrate is plastic. In a further embodiment the substrate is formed from a formulation comprising recycled plastic. In another embodiment the substrate is metal.

In a further embodiment, wherein when the photovoltaic shingle is installed on a surface of a building structure or a roof structure that requires a plurality of rows of the photovoltaic shingle to completely cover the structure, the surface can be at least about 85% covered by the photovoltaic cells of the photovoltaic assemblies except for an area of the surface directly under the upper area of the outward face of the last row of photovoltaic shingles, and the end of the last shingle in each of the rows.

In another embodiment the substrate comprises an integral riser between a lower tier and an upper tier and the photovoltaic assembly comprises a first photovoltaic cell assembly and a second photovoltaic assembly.

The first photovoltaic assembly is affixed to, and conformed to, the outward face of the lower tier of the substrate and comprises a first photovoltaic cell that spans at least the lower tier except for a portion thereof that is intended to be overlapped by another shingle, and except for a narrow peripheral band around a periphery of the lower tier of the substrate.

The second photovoltaic cell assembly is affixed to, and conformed to, the outward face of the upper tier of the substrate and comprises a second photovoltaic cell that spans at least the upper tier except for a portion thereof that is intended to be overlapped by another shingle, and except for a narrow peripheral band around a periphery of the upper tier of the substrate.

In a further embodiment the narrow peripheral bands in both the lower and upper tiers are no greater than about one inch (25 mm) in width around a periphery of the lower tier of the substrate. In a still further embodiment the narrow peripheral bands are about 0.5 inches (13 mm) in width.

In a further embodiment the integral riser further comprises offset means for maintaining side-to-side horizontal alignment of the integral risers.

In one embodiment the substrate has two tiers and two ridges and two troughs. In another embodiment the substrate has at least two tiers, and at least two ridges and at least two troughs. In still another embodiment the substrate has two tiers and about five ridges and about four troughs. In yet another embodiment the substrate has two tiers and about twenty ridges and about nineteen troughs. In another embodiment the substrate has three tiers and about three ridges and about two troughs. Various other shingles featuring other combinations of number of tiers, number of ridges, and number of troughs can be made using the principles of this invention. In this manner shingles as large as about 4 feet (120 cm) by 8 feet (250 cm) can be made.

This invention also includes a method of producing a photovoltaic shingle from a selection of customized colors. The method comprises producing a substrate having a Spanish tile-like shape with a plurality of ridges and troughs and a repetitive profile from a plastic composition.

A first metal conductor member is formed on the lower area of the substrate so that the first metal conductor member conforms to and is affixed to the substrate. A first color-imparting member is formed over the first metal conductor member so that the first color-imparting member conforms to and is affixed to the first metal conductor member.

A first member having a first semiconductor composition is formed over the first color-imparting member so that the first semiconductor composition conforms to and is affixed to the first color-imparting member.

A second metal conductor member is formed over the first semiconductor composition so that the second metal conductor member conforms to and is affixed to the first semiconductor composition.

A second member having a second semiconductor composition is formed over the second metal conductor member so that the second semiconductor composition conforms to and is affixed to the second metal conductor member, thereby producing a photovoltaic cell.

A second member having a second color-imparting composition is formed over the second semiconductor composition so that the second color-imparting composition conforms to and is affixed to the second semiconductor composition.

The method further comprises forming a translucent encapsulating or sealer member over the second member of a second color-imparting composition so that the sealer member conforms to and is affixed to the second color-imparting composition, thereby producing the photovoltaic shingle of a particular selected customized color. The translucent sealer member being effective for preventing the photovoltaic cell from being damaged by rain.

In another embodiment the method further comprises preparing a mold for producing the substrate with the Spanish tile-like shape. Then producing the substrate from the plastic composition using the mold, and removing the substrate produced from the mold and using the plastic substrate for producing the photovoltaic shingle.

In a further embodiment the plastic composition used to produce the substrate is a recycled plastic.

In one embodiment the first metal conductor member can be in the configuration of a thin grid or a thin film with a thickness between about 4 mils and about 6 mils.

In one embodiment the first member of color-imparting composition is a thin translucent film with a thickness between about 0.5 mils and about 1.5 mils.

In one embodiment the first member of semiconductor composition is a film with a thickness between about 50 nm and about 20,000 nm. The unit “nm” means a nanometer.

In one embodiment the second metal conductor member is a thin grid or a thin with a thickness between about 4 mils and about 6 mils.

In one embodiment the second member of semiconductor composition is a film with a thickness between about 50 nm and about 20,000 nm

In one embodiment the second member of a color-imparting composition is a film with a thickness between about 1.5 mils and about 3 mils.

In one embodiment the translucent sealer member is a film with a thickness between about 15 mils and about 25 mils.

In one embodiment the composition of the first semiconductor member comprises carbon nanostructures for enhancing electrical conductivity.

In one embodiment the composition of the second semiconductor member comprises carbon nanostructures for enhancing electrical conductivity.

In one embodiment the substrate is plastic and has a thickness between about 0.20 inches and about 0.40 inches.

Plastic forming materials that can be used to produce the plastic substrate by molding processes are molding materials. Examples of molding materials are polypropylenes, polyvinyl chlorides or PVC's, and acrolonitrile butadiene styrene or ABS. Examples of molding processes useful for the substrate are injection molding, thermoset molding, vacuum molding, pressure molding and stamping.

Various deposition processes can be used to produce one or more of the layers in the thin film photovoltaic cells including chemical deposition and vapor deposition processes.

Various compositions of photovoltaic cells that can also be used. For example the following photovoltaic cells can be used in this invention are organic polymers with nano structures, cadmium/telluride, copper, indium, gallium, diselenide or CIGS, amorphorous silicon, and silicon. These products are sold by Konarka, First Solar, Nano Solar and Uni Solar. Konarka's thin film photovoltaic cell is a polythiaphene-fullerene hetrajunction polymer with an epoxy functionalized fullerene C60 fixer having poly cyclopental dithiaphene alt benzothiadiazole (PCPDTBT) with PCBM pheynel butyric acid me ester fullerene derivative, which are organic polymer photovoltaic cells. The metal conductors are silver.

The method of producing the photovoltaic shingles of this invention include continuous line operations where the substrates are produced, then conveyed to the photovoltaic cell application operation, then to photovoltaic cell encapsulation operation, then to the electrical completion operation, and then to packaging for shipment to vendors.

Some manufacturing methods for producing the photovoltaic shingles are (1) injection molding the substrate, laminating the photovoltaic assembly using an adhesive from 3M®, and sealing with a polymer, an acrylic or Teflon® protective layer, (2) embedding the photovoltaic assembly into the injection molded substrate, and (3) injection molding the substrate, direct deposition of the photovoltaic assembly, and sealing with a polymer, an acrylic or Teflon® protective layer.

### BRIEF DESCRIPTION OF THE DRAWINGS

FIG. 1 is a perspective view of a first embodiment of a single tier substrate with ridges for side to side substrate overlapping.

FIG. 2 is a plan view of the outward face of the substrate in FIG. 1.

FIG. 3 is a plan view of the inward face of the substrate in FIG. 1.

FIG. 4 is a cross-sectional view of the substrate in the direction of arrows 4 of FIG. 2.

FIG. 5 is a cross-sectional view of the substrate in the direction of arrows 5 of FIG. 2.

FIG. 6 is an end view in the direction of arrows 6 of FIG. 1.

FIG. 7 is a profile of the lower edge of the substrate of FIG. 1.

FIG. 8 is an end view of a second embodiment of a substrate of FIG. 1 but with integral bird stops.

FIG. 9 is a perspective view of a first embodiment of a shingle of FIG. 1 with three ridges having exposed photovoltaic cells.

FIG. 10 is a plan view of the outward face of the shingle in FIG. 9.

FIG. 11 is a cross-sectional view of the shingle in the direction of arrows 12 in FIG. 10.

FIG. 12 is a cross-sectional view of shingle in the direction of arrows 13 in FIG. 10.

FIG. 13 is an end view of shingle in the direction of arrows 13 in FIG. 9.

FIG. 14 is a profile of the lower edge of the shingle of FIG. 9.

FIG. 15 is an end view of a second embodiment of a shingle with integral bird stops.

FIG. 16 is a perspective view of a third embodiment of a two tier substrate with ridges for side-to-side substrate overlapping.

FIG. 17 is a plan view of the outward face of the substrate in FIG. 16.

FIG. 18 is a plan view of the inward face of the substrate in FIG. 17.

FIG. 19 is a cross-sectional view of the substrate in the direction of arrows 19 of FIG. 17.

FIG. 20 is a cross-sectional view of the substrate in the direction of arrows 20 in FIG. 17.

FIG. 21 is an end view of the substrate in the direction of arrows 21 in FIG. 16.

FIG. 22 is a profile of the lower edge of the substrate of FIG. 17.

FIG. 23 is an end view of a fourth embodiment of a substrate with integral bird stops.

FIG. 24 is a perspective view of a third embodiment of a two tier shingle with three ridges having exposed photovoltaic cells.

FIG. 25 is a plan view of the outward face of the shingle in FIG. 25.

FIG. 26 is a cross-sectional view of the shingle in the direction of arrows 26 in FIG. 25.

FIG. 27 is a cross-sectional view of the shingle in the direction of arrows 27 in FIG. 25.

FIG. 27A is an enlarged detail of area 27A in FIG. 29.

FIG. 27B is an enlarged detail of area 27B in FIG. 29.

FIG. 27C is an enlarged detail of area 27C in FIG. 29.

FIG. 28 is an end view of shingle in the direction of arrows 28 in FIG. 24.

FIG. 29 is a profile of the lower edge of the shingle of FIG. 24.

FIG. 30 is an end view of a fourth embodiment of a substrate with integral bird stops.

FIG. 31 is a perspective view of a fifth embodiment of a shingle with two tiers and three ridges having exposed photovoltaic cells.

FIG. 32 is a perspective view of a sixth embodiment of a single tier shingle with a smaller radius of curvature for its troughs and with three of the four ridges having exposed photovoltaic cells.

FIG. 33 is a profile of the lower edge of the shingle of FIG. 32.

FIG. 34 is a perspective view of a seventh embodiment of a shingle with flat troughs.

FIG. 35 is a profile of the lower edge of the shingle of FIG. 34.

FIG. 36 is a perspective view of an eighth embodiment of a shingle with flat troughs and two tiers.

FIG. 37 is a profile of the lower edge of the shingle of FIG. 36.

FIG. 38 is a detail of side-to-side overlapping substrates.

FIG. 39 is a detail of side-to-side interlocking substrates.

FIG. 40 is a prospective detail of the FIG. 39.

FIG. 41 is a photovoltaic assembly layers.

FIG. 42 is a simple photovoltaic cell with a basic number of layers.

FIG. 43 is a detail of an electrical jack for photovoltaic shingle.

FIG. 44 is a schematic for electrical connection of an array of shingles to an electric grid.

FIG. 45 is an array of the shingles like those of FIG. 9 on a roof structure.

FIG. 46 is an array of the shingles having two tiers like those of FIG. 24 on a roof structure.

### DESCRIPTION OF THE PREFERRED EMBODIMENTS

In the several embodiments of this invention that will now be described the last two digits usually refer to elements with a similar function or characteristic, e.g. element nos. 11, 111, 211, 311, 411 and 511 are substrates, and element nos. 10, 110, 210, 310, 410 and 510 are shingles. Likewise element nos. 27 and 127 represent phantom lines defining areas on the substrates for similar purposes.

The photovoltaic shingle of this invention comprises a base portion and an energy conversion and power producing portion. The base portion comprises a substrate and the energy and power producing portion comprises a photovoltaic assembly.

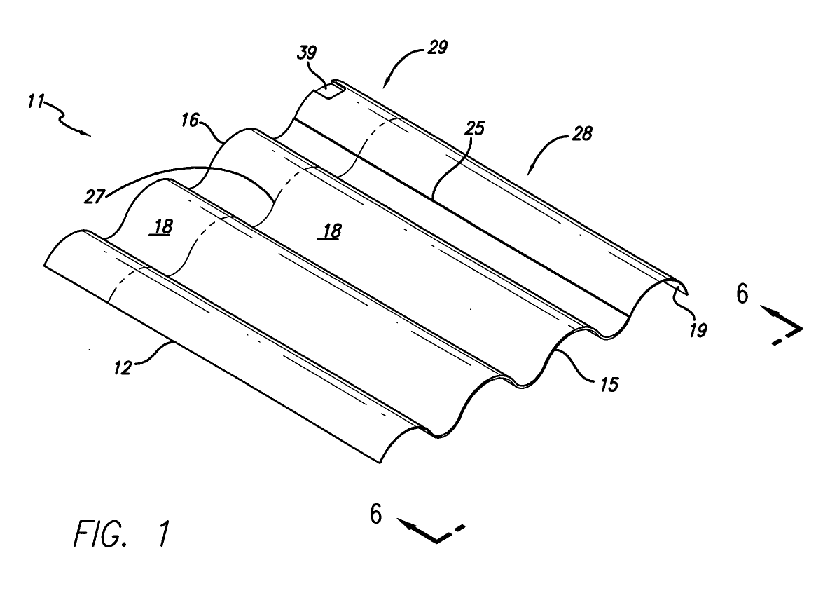

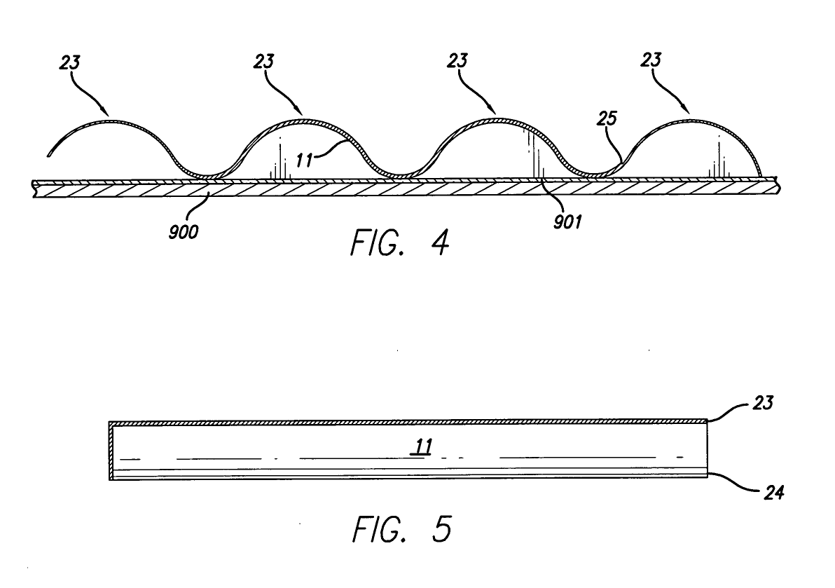

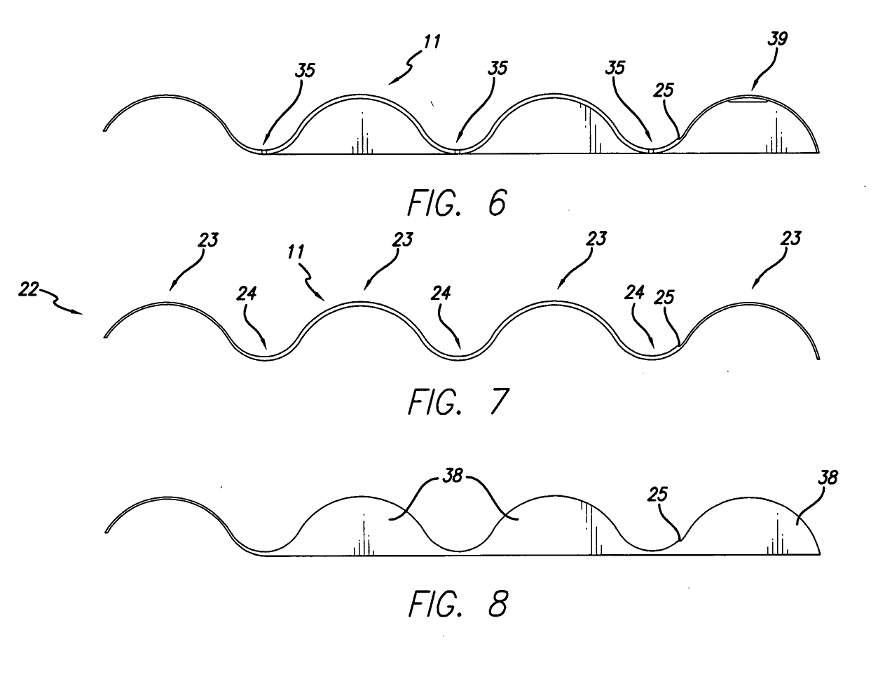

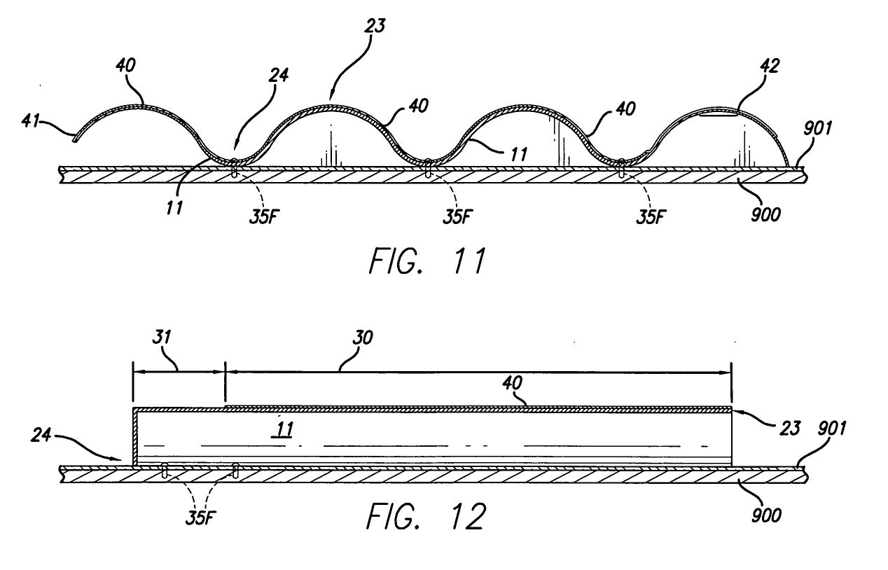

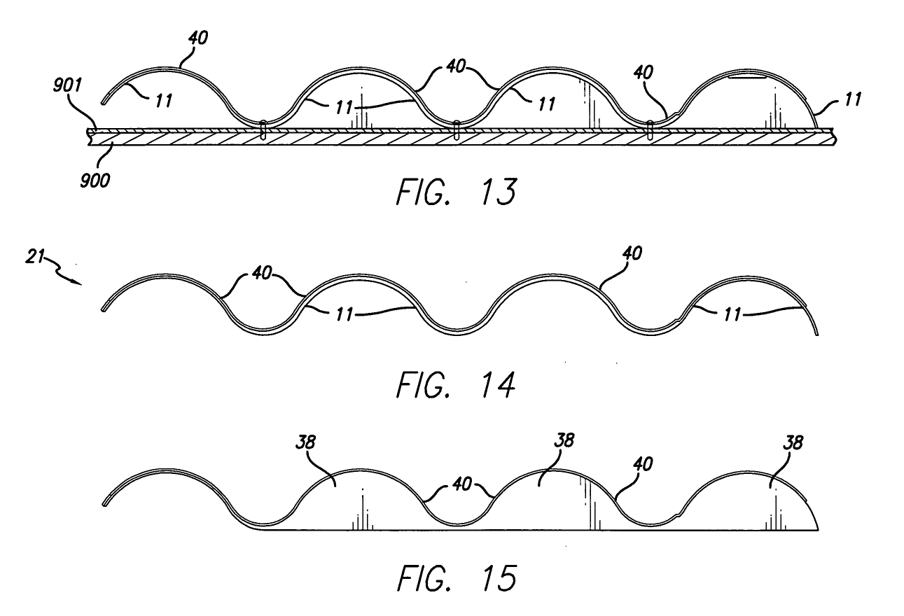

FIGS. 1-7 and 9-14 illustrate a first embodiment of a substrate 11 and a shingle 10 of this invention. In particular the base portion of shingle 10 comprises a substrate 11 having a left side 12, a right side 13, a length 14, a bottom end 15, a top end 16, a width 17, an outward face 18 and an inward face 19. The substrate has an end profile 22 as seen in FIG. 7 that simulates a Spanish style-like shaped roofing tile with a plurality of parallel ridges 23 that are separated by a plurality of parallel troughs 24.

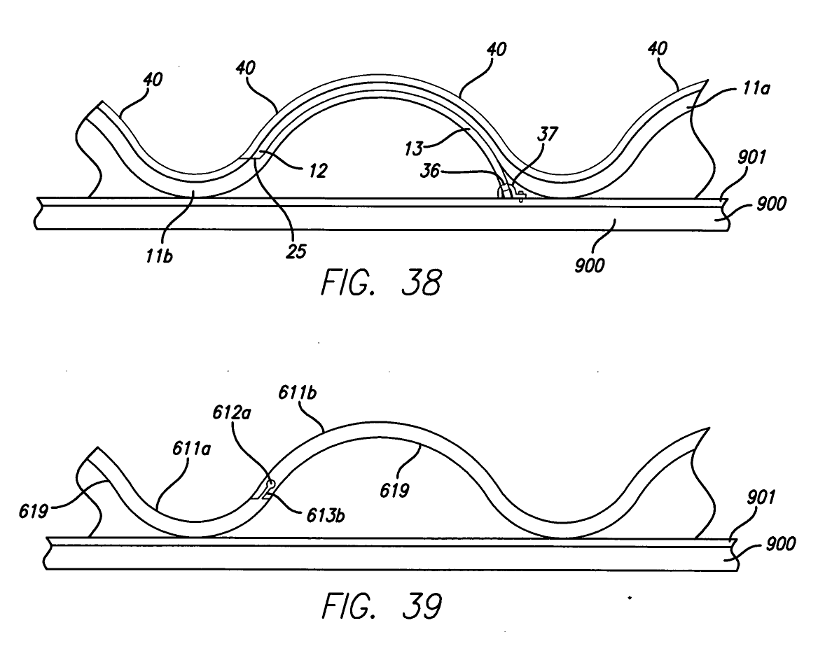

In this embodiment the left side 12 of one substrate 11a is designed to nest over the right side 13 and to abut ledge 25 of an adjacent substrate 11b of like character as illustrated in FIG. 38.

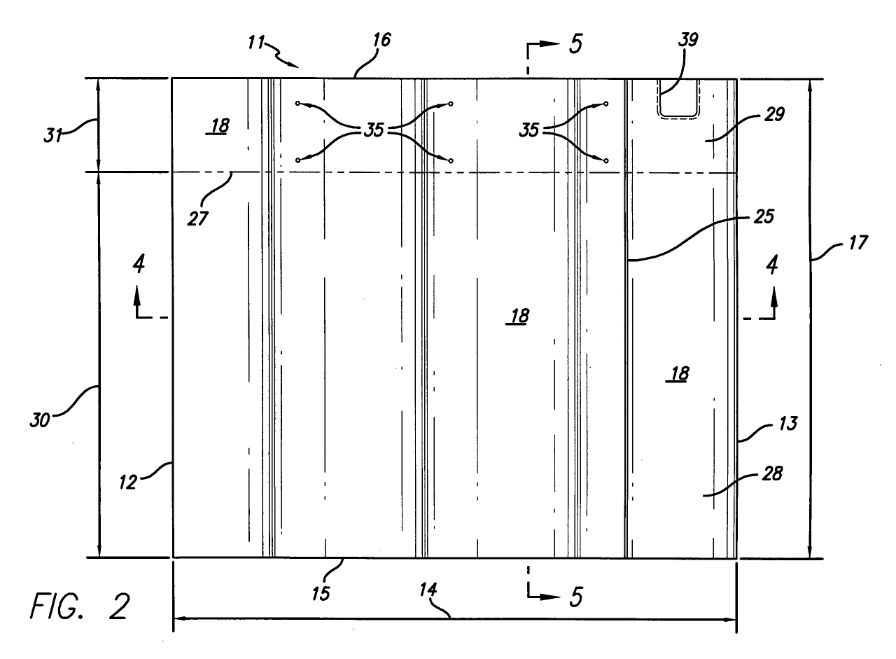

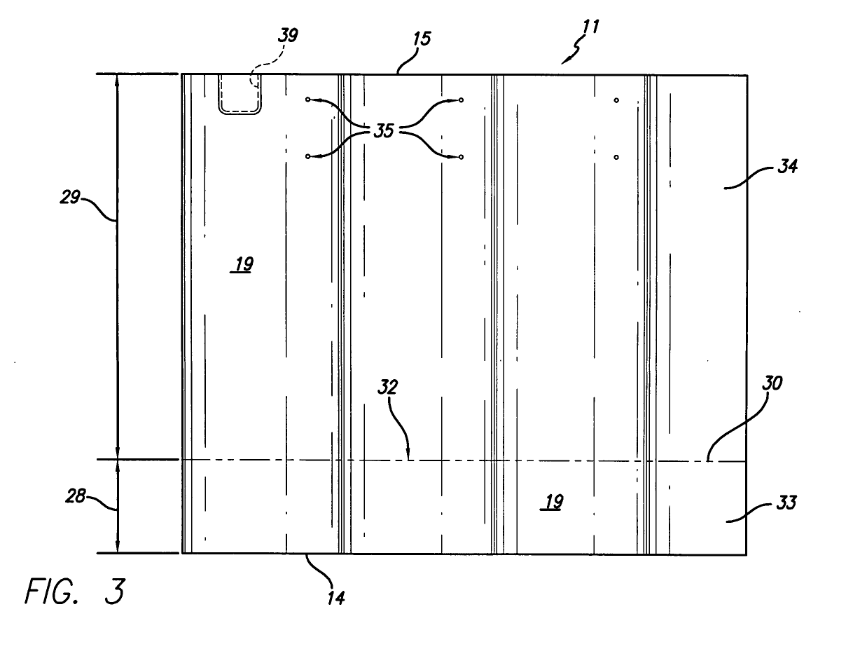

As seen in FIG. 2, the outward face 18 of the substrate has a lower area 28 and an upper area 29 that are separated at and by a phantom line 27 such that the lower area has a width 30 and the upper area has a width 31. Likewise, as seen in FIG. 3, the inward face 19 of the substrate has a lower area 33 and an upper area 34 that are separated at and by a phantom line 32.

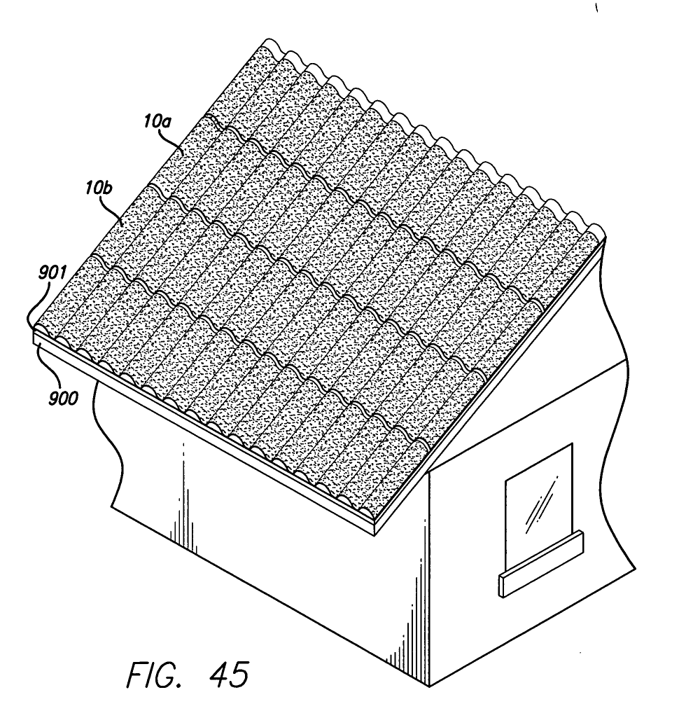

The substrate is designed so that the lower area 33 of the inward face 19 of the substrate of an upper shingle 10a nests and aligns over the upper area 29 of the outward face 18 of the substrate of a lower shingle 10b of like character as indicated in FIG. 45 thereby having the characteristic of Spanish style-like shaped tiles arranged in overlapping rows.

The low point of each trough 24 in the upper area 29 has apertures 35 for receiving fastener means for securing the substrate 11 and hence the shingle 10 directly to, and abutted against a typically wooden roof structure 900, often 0.75 inch plywood sheeting, with a layer of moisture/insulating barrier 901, e.g. roofing felt, therebetween, as shown in the figures. The substrate and hence shingle, is secured to roof structure without an auxiliary support or framing structure for spacing the shingle above and away from the roof structure. The roofing felt is placed between the roof structure and the shingle only as a moisture and/or insulating barrier and not as an auxiliary support or framing structure. The apertures and fasteners are covered by the next row of shingles thereby preventing rain from entering through the apertures to the roof structure. Examples of a fastener means include screws, bolts and nails.

As seen in FIG. 38, the lower right end of each substrate of each shingle has a slot 36 for receiving a clip 37 for securing the shingle directly to and abutted against the wooden roof structure 900 and barrier 901. One end of the clip can be installed through the slot from outside the shingle and the other end of the clip fastened directly to the roof structure so that the shingle directly abuts the roof structure, except for barrier therebetween. Since the next adjacent shingle in the series will cover the slot 36 and clip 37, rain is prevented from entering over the clip and through the slot to the roof structure 900. This feature enables the lower end of each shingle, regardless of the particular row that the shingle is in, to be secured directly to the roof structure 900.

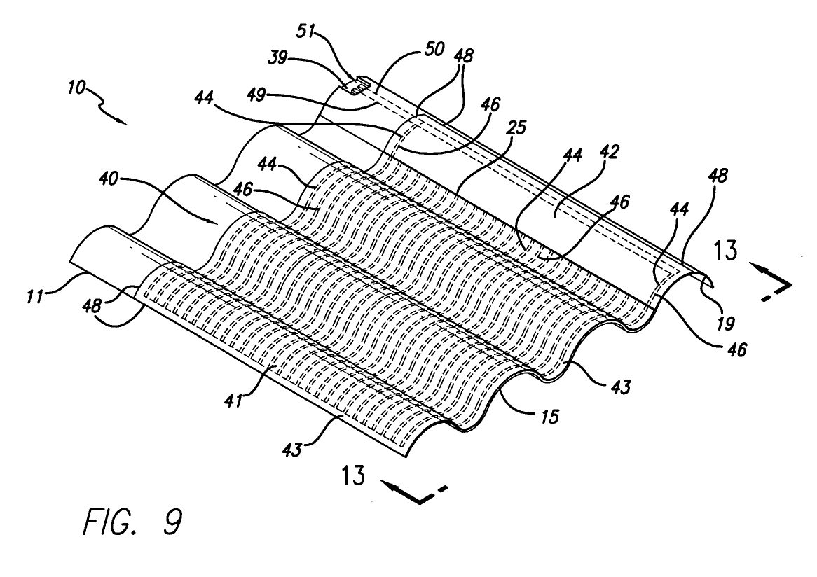

The photovoltaic shingle of this invention comprises an energy producing portion on top of the substrate as illustrated in FIGS. 9-15. The energy and power producing portion comprises a photovoltaic assembly 40 that comprises a photovoltaic cell 41. The photovoltaic cell covers the lower area 28 of the outward face 18 of the substrate except for a narrow peripheral band 43 around the bottom end 15 and the left end 12 of the substrate, and except for a portion 42 of the right side of the substrate between the ledge 25 and the right end 13 of the substrate.

The upper area 29 that is overlapped by at least one other shingle is not covered by the photovoltaic cell. Since the areas of the shingle that are overlapped by another shingle will not receive incident sun light there would be no benefit to having a photovoltaic cell in such overlapped areas.

Referring also to FIG. 42, a photovoltaic cell 41 comprises a first metal conductor member 44 over the outward face 18 of the substrate, a first semiconductor member 45, a second metal conductor member 46, and a second semiconductor member 47. Photovoltaic cell 41 converts solar radiation to electrical energy. Photovoltaic cell 41 is protected by a transparent sealer member 48 that encapsulates and seals the photovoltaic cell 41 to the substrate 11. Sealer member 48 is effective for preventing the photovoltaic cell, when the shingle is installed on a roof structure, from being damaged by rain. Photovoltaic assembly 40 comprises photovoltaic cell 41 and sealer member 48.

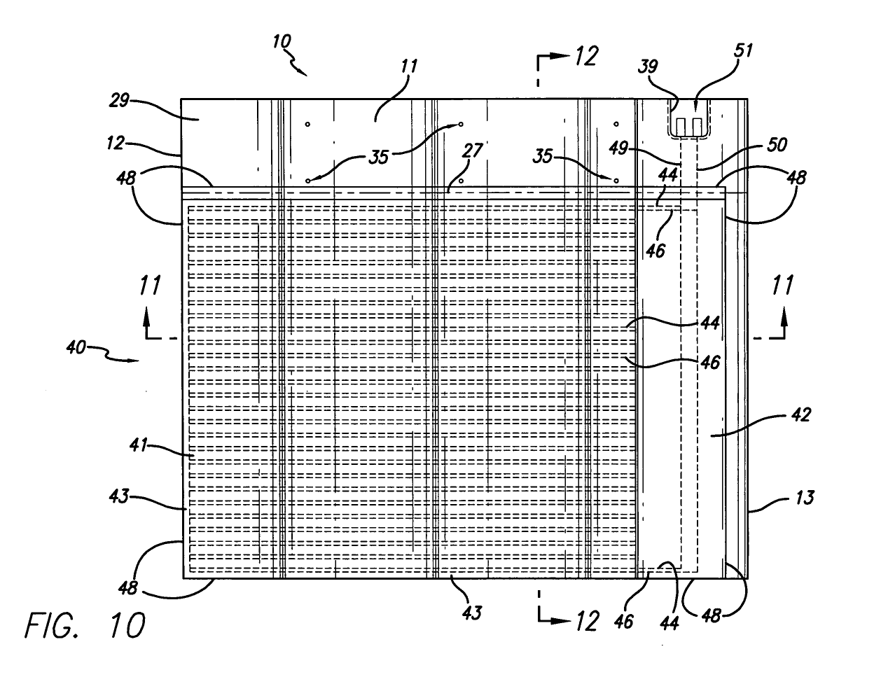

Metal conductor members 44 and 46 preferably are configured in a grid pattern and function as anode and cathode conductors for the power produced by the photovoltaic cell. Members 44 and 46 are connected electrically to conductors 49 and 50 (shown only for the uppermost and lowermost members 44 and 46 in FIGS. 9 and 10). Conductors 49 and 50 are connected electrically to electrical jack 51 that is attached to a recess 39 in the substrate.

Sealer member 48 extends over conductors 49 and 50 into portion 42 of the substrate 11, and over and above phantom line 27 into upper area 29.

The shingle has an end profile 21 as seen in FIG. 14.

The narrow peripheral band 43 is wide enough to seal the photovoltaic cell 41 to the substrate. A width of about 0.5 inches (13 mm) is wide enough to effectively seal the photovoltaic cell to the substrate and protect the photovoltaic cell thereof.

In one embodiment of this invention the photovoltaic cell is a thin film photovoltaic cell.

In one embodiment the first metal conductor member 44 is a grid with strips about 3 mm wide, spaced about 15 mm apart and having a thickness between about 4 mils and about 6 mils.

In one embodiment the first semiconductor member 45 is film having a thickness between about 50 nm to about 20,000 nm.

In one embodiment the second metal conductor member 46 is a grid with strips about 3 mm wide, spaced about 15 mm apart and having a thickness between about 4 mils and about 6 mils.

In one embodiment the second semiconductor member 47 is film having a thickness between about 50 nm to about 20,000 nm.

In one embodiment the transparent sealer member 48 is film having a thickness between about 15 mils to about 25 mils.

In one embodiment the substrate is plastic and has an average thickness of about 0.25 inches (6 mm).

In one embodiment the radius of curvature of the ridges 23 is about 4 inches (10 cm) and the troughs 24 is about 2.5 inches (6.4 cm).

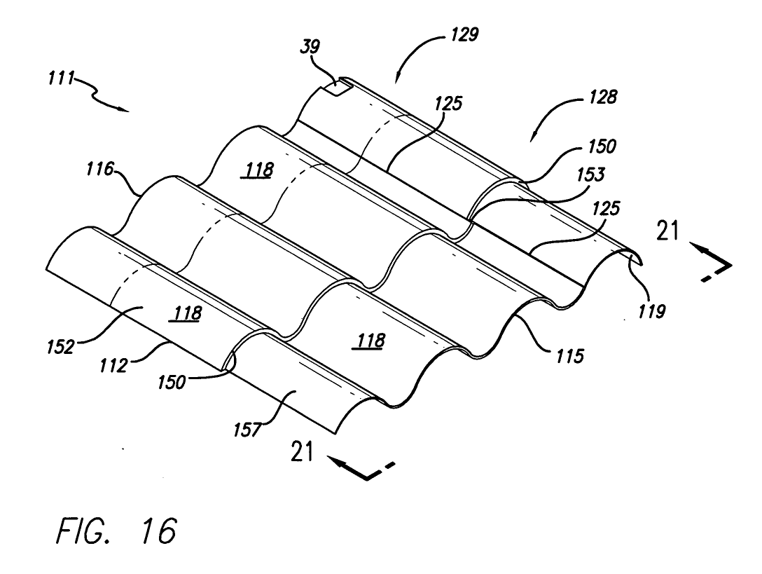

In a second embodiment that is similar to the first embodiment except that the first row, i.e. lowest row of shingles, on a roof structure, has a substrate that includes an integral lower end closures 38, sometimes referred to as bird stops, as seen in the end views of FIGS. 8 and 16 instead of the opened end views of FIGS. 7 and 15, respectively. All other features of the substrate and shingle are the same as described and shown for the first embodiment of this invention.

In a third embodiment of this invention the shingle also has a base portion and an energy and power producing portion, and the base portion comprises a substrate that has two tiers separated by an integral riser that has the visual effect of appearing to have two independent rows of shingles. In this embodiment the energy and power producing portion comprises two photovoltaic assemblies, namely a lower and upper photovoltaic assembly separated by the integral riser.

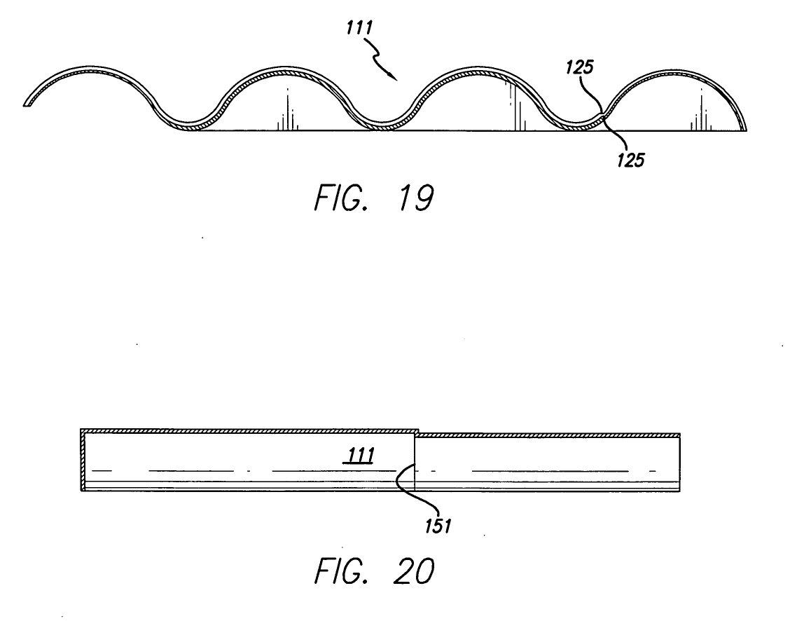

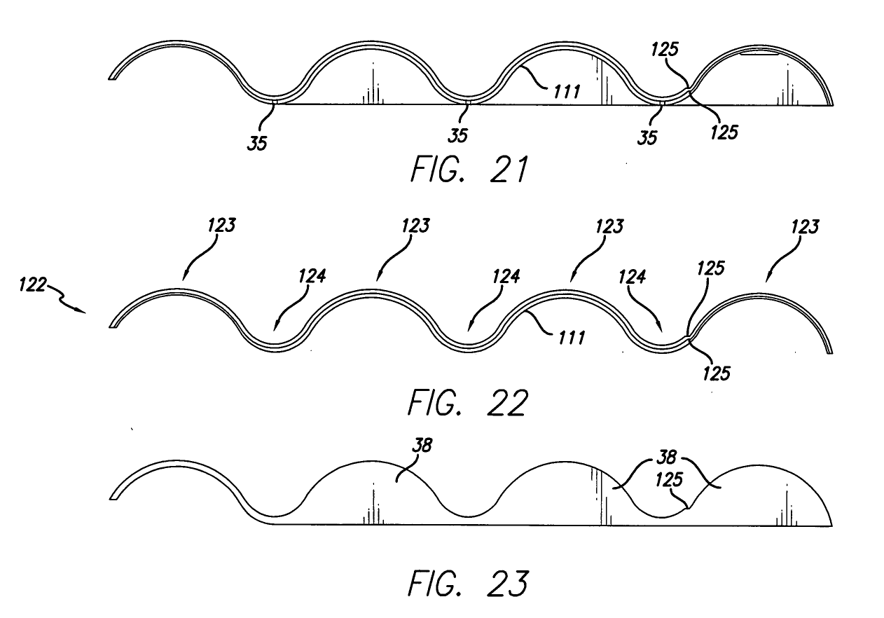

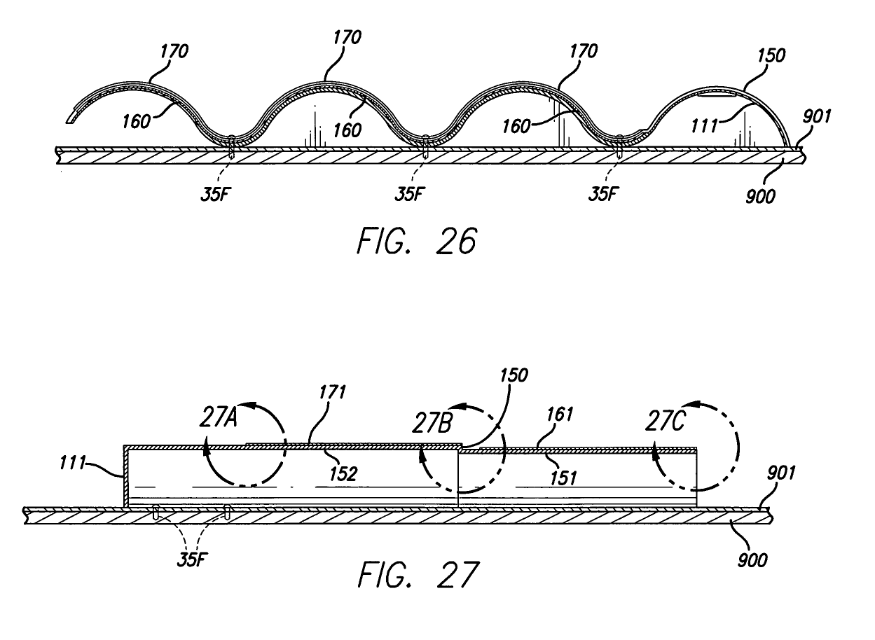

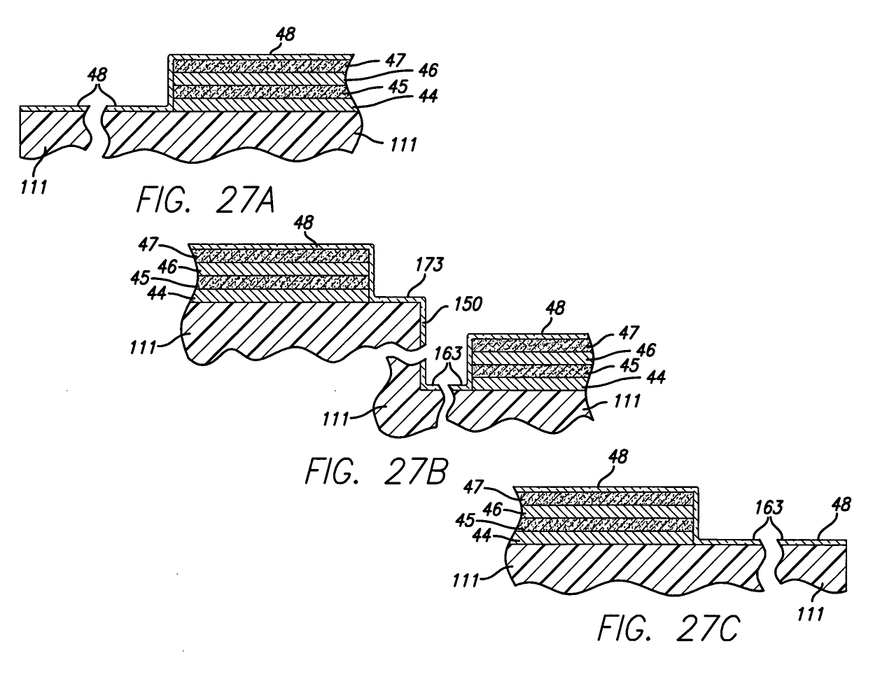

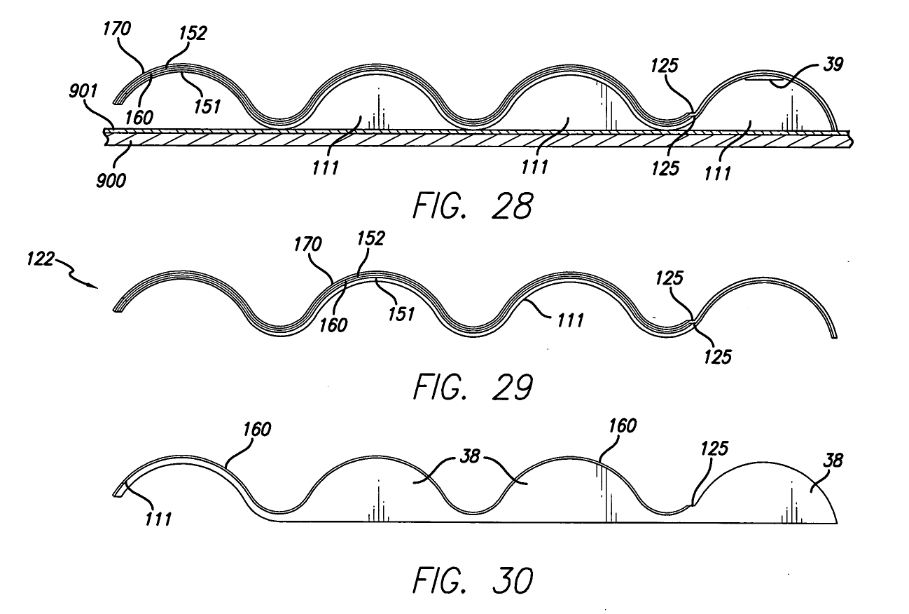

For example, FIGS. 16-22 and 24-29 illustrate the third embodiment of the substrate 111 and shingle 110 of this invention. In particular the base portion of shingle 110 comprises a substrate 111 having a left side 112, a right side 113, a length 114, a bottom end 115, a top end 116, a width 117, an outward face 118 and an inward face 119.

The substrate has an end profile 122 as seen in FIG. 22 that has a plurality of parallel ridges 123 that are separated by a plurality of parallel troughs 124.

In this embodiment the left side 112 of one substrate is designed to nest over the right side 113 and to abut ledge 125 of an adjacent substrate of like character in a manner similar to the first embodiment that was described earlier and illustrated in FIG. 38.

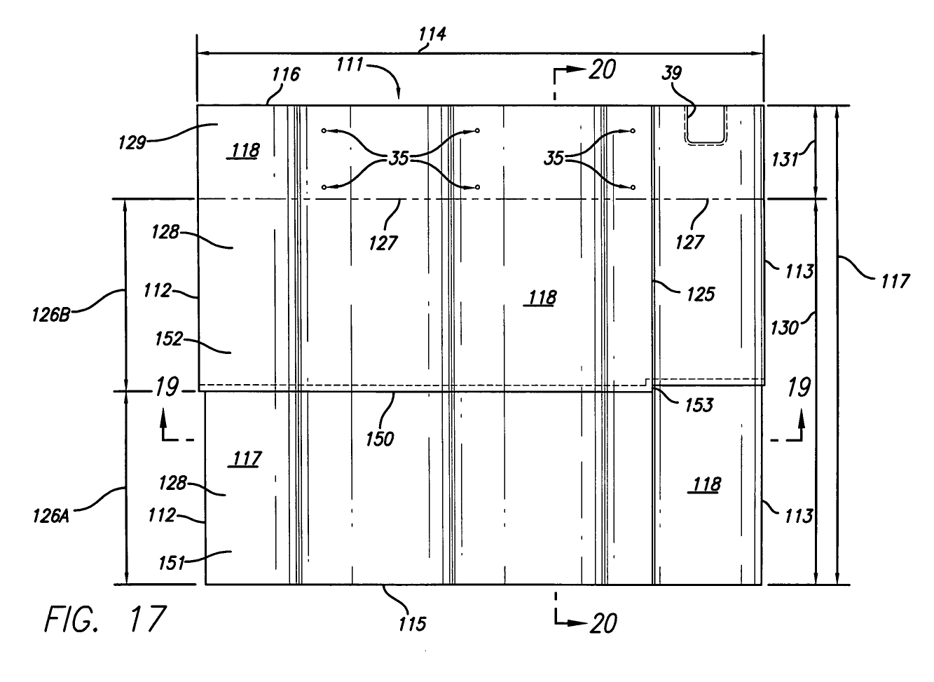

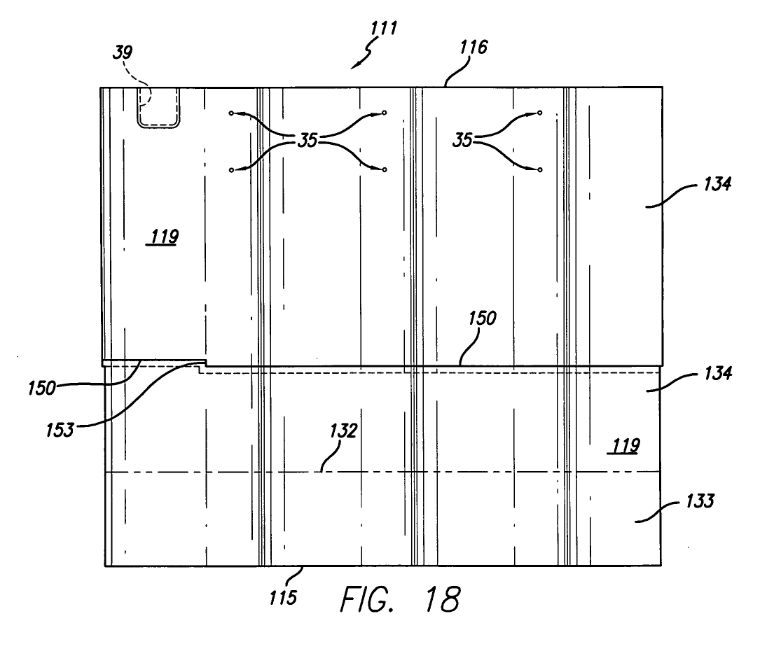

As seen in FIG. 17, the outward face 118 of the substrate has a lower area 128 and an upper area 129 that are separated at and by a phantom line 127 such that the lower area has a width 130 and the upper area has a width 131. Likewise, as seen in FIG. 18, the inward face 119 of the substrate has a lower area 133 and an upper area 134 that are separated at and by a phantom line 132.

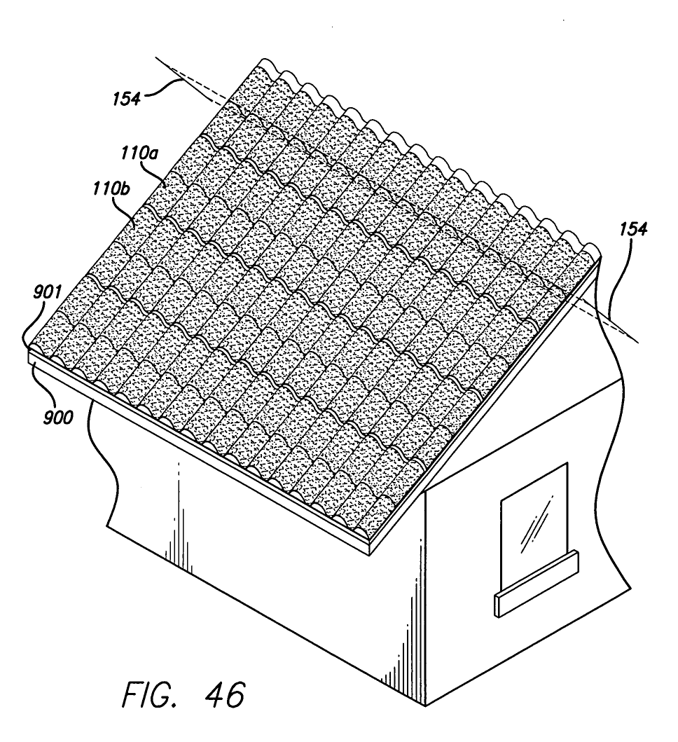

The substrate is designed so that the lower area 133 of the inward face 119 of the substrate of an upper shingle 110a nests and aligns over the upper area 129 of the outward face 118 of a substrate of a lower shingle 110b of like character as illustrated in FIG. 46 thereby having the characteristic of two independent rows of Spanish style-like shaped shingles or tiles when there is only one row of the shingles of this embodiment of this invention but with two tiers.

The low point of each trough 124 in the upper area 129 has apertures 35 for receiving fastener means for securing the substrate 111 and hence the shingle 110 directly to, and abutted against a typical wooden roof structure 900, often 0.75 inch plywood sheeting, with a layer of barrier 901 therebetween, as shown in the figures, without an auxiliary support or framing structure for spacing the shingle above and away from the roof structure. The barrier 901 is used as a moisture and/or insulating barrier. As in the first embodiment described above, the apertures and fasteners are covered by the next row of shingles thereby preventing rain from entering through the apertures to the roof structure.

The lower right end of each shingle has a slot for receiving a clip for securing the shingle directly to and abutted against the wooden roof structure 900 and barrier 901 in the same manner as described for the first embodiment with reference to FIG. 38.

The substrate has a lower tier 151 having width 126A and an upper tier 152 having width 126B separated by an integral riser 150. The sum of width 126A and 126B equals the width 130 of lower area 128. In this embodiment widths 126A and 126B are equal.

In this embodiment a portion of riser 150 includes an offset means for maintaining side-to-side alignment of the risers in a row of shingles in an inclined plane 154 perpendicular to the plane of the roof's sheeting. For example, at ledge 125 riser 150 has an offset 153 that is parallel to the ridges 123 and troughs 124 so that when the shingles are installed side-to-side on a roof structure, the risers will be in alignment with each other in an inclined plane 154 as indicated in FIG. 46.

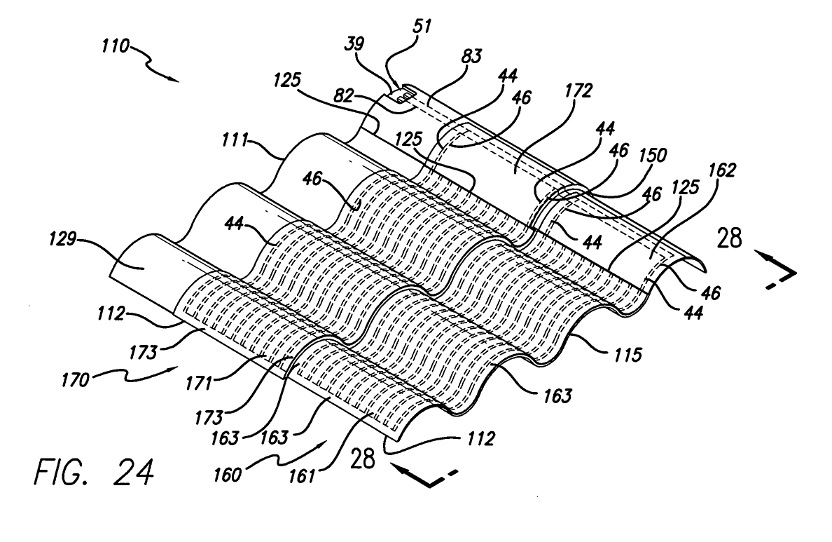

The photovoltaic shingle also comprises an energy and power producing portion on top of the substrate as illustrated in FIGS. 24-29. The energy and power producing portion has the two photovoltaic assemblies 160 and 170 on substrate tiers 151 and 152, respectively, that comprises photovoltaic cells 161 and 171, respectively.

The photovoltaic cells cover the lower area 128 of the outward face 118 of the substrate except for narrow peripheral bands 163 and 173 of photovoltaic assemblies 160 and 170, respectively, around the bottom end 115 and the left end 112 of the substrate and around the periphery of the riser 150, and further except for portions 162 and 172 of the right side of the substrate between the ledge 125 and the right end 113 of the substrate. The upper area 129 that is overlapped by at least one other shingle is not covered by the photovoltaic cell since areas that are overlapped will not receive incident sun light.

The photovoltaic cells 161 and 171 are constructed and function in the same manner as described with regard to the first embodiment of this invention and FIG. 42.

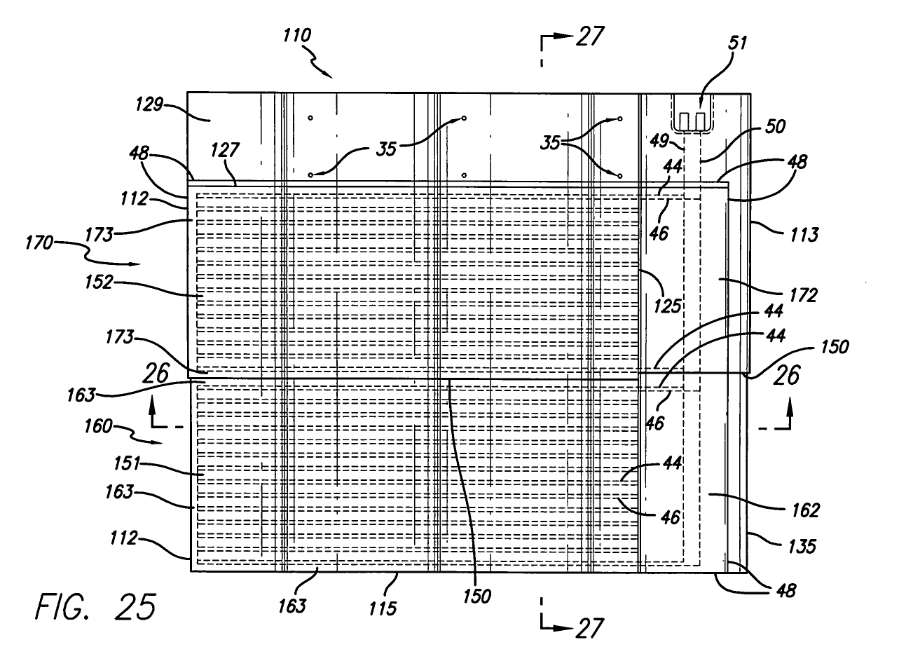

With regard to photovoltaic cells 161 and 171, metal conductor members 44 and 46 preferably are configured in a grid pattern and function as an anode and cathode conductors for the power produced by the photovoltaic cell. Members 44 and 46 are connected electrically to conductors 49 and 50 (shown only for the uppermost and lowermost members 44 and 46 in FIGS. 24 and 25). Conductors 49 and 50 are in turn connected electrically to electrical jack 51 that is attached to a recess 39 in the substrate. Sealer member 48 extends over conductors 49 and 50 and is also extended above phantom line 127 into upper area 129.

The shingle has an end profile 121 as seen in FIG. 29.

In the third embodiment the radius of curvature of the ridges 123 is about 4 inches (10 cm) and the troughs 124 is about 2.5 inches (6.4 cm).

In a fourth embodiment that is similar to the third embodiment except that the first row, i.e. lowest row of shingles on a roof structure, has a substrate that includes an integral lower end closures 38, sometimes referred to as bird stops, as seen in the end views of FIGS. 23 and 30 instead of the opened end views of FIGS. 22 and 29, respectively. All other features of the substrate and shingle are the same as described and shown for the third embodiment.

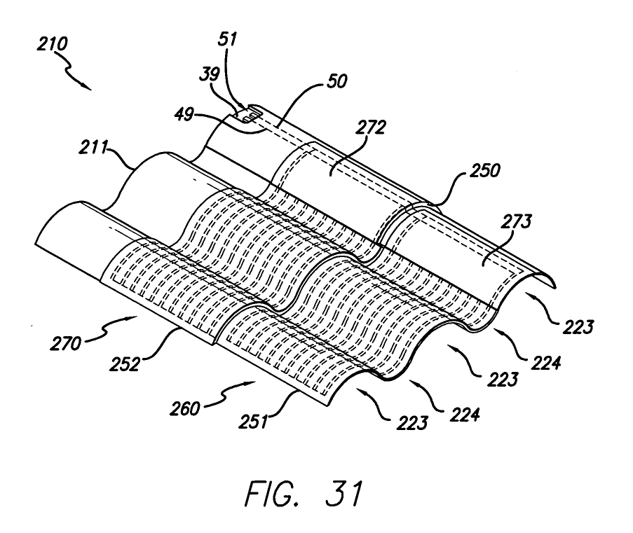

FIG. 31 is a fifth embodiment of a shingle 210 of this invention similar to the shingle 110 as seen in FIG. 24. Shingle 210 comprises substrate 211, which has a lower tier 251 and an upper tier 252 separated by an integral riser 250, and three parallel ridges 223 and two parallel troughs 224 that span the integral riser. Shingle 210 also comprises a lower photovoltaic assembly 260 and an upper photovoltaic assembly 270, which are affixed tiers 251 and 252, respectively and span two adjacent ridges.

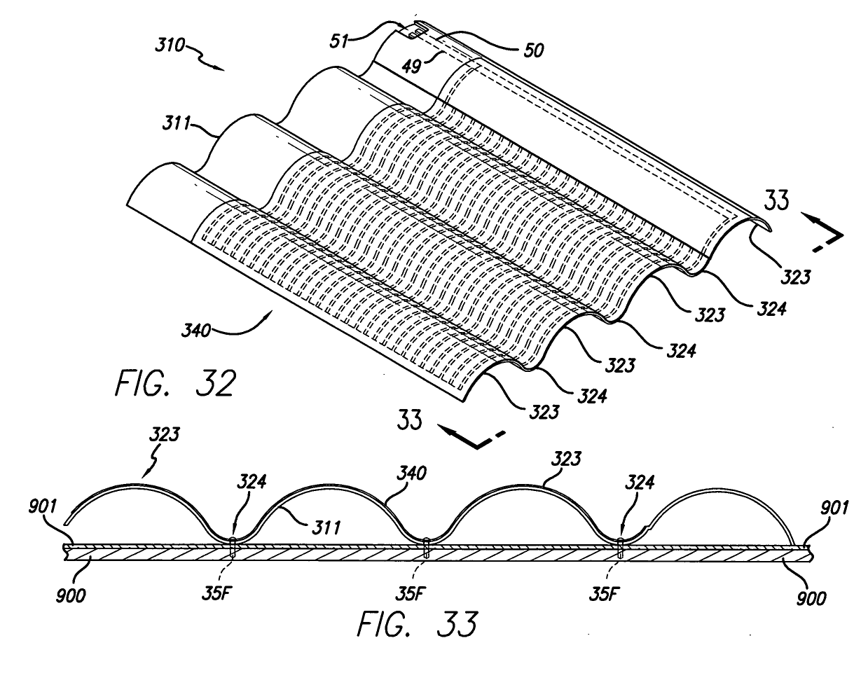

FIG. 32 is a sixth embodiment of a shingle 310 of this invention similar to the first embodiment of a shingle 10 in FIG. 9. Shingle 310 comprises single tier substrate 311 and a photovoltaic assembly 340.

Shingle 310 has an end profile 321 as seen in FIG. 33 that simulates a Spanish style-like shaped roofing tile with a plurality of parallel ridges 323 that are separated by a plurality of parallel troughs 324. The end profile of FIG. 33 is different than the end profile of shingle 10 shown in FIG. 14 in that the radius of curvature of the ridges 323 are about the same as ridges 23, however, the radius of curvature of troughs 324 is smaller than the radius of curvature of troughs 24.

In one embodiment the radius of curvature of the ridges 323 is about 4 inches (10 cm) and the radius of curvature of the troughs 324 is about 1.5 inches (3.8 cm).

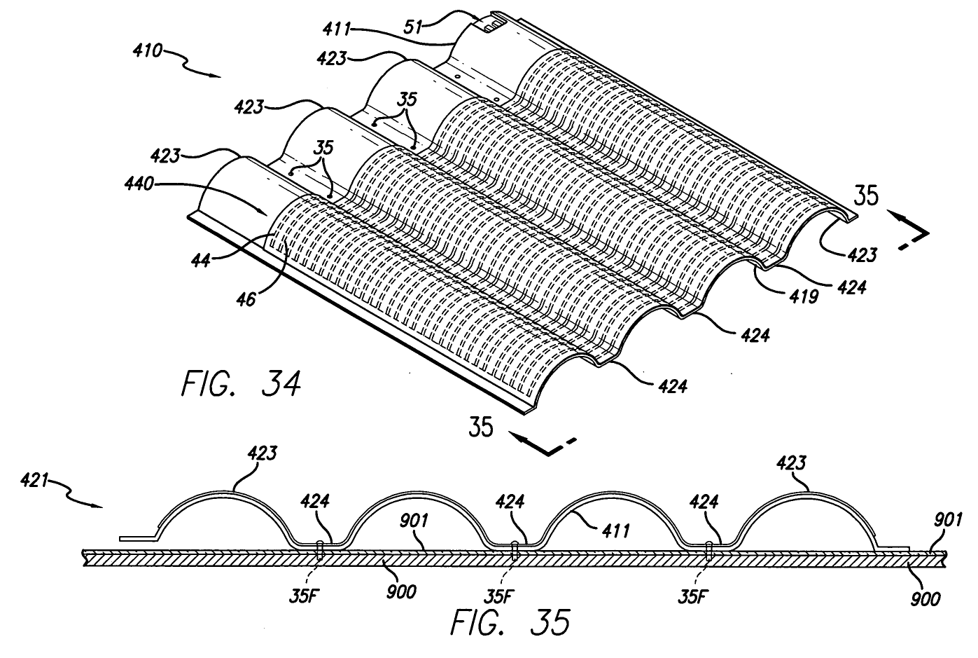

FIG. 34 is a seventh embodiment of a shingle 410 of this invention similar to the third embodiment of a shingle 10 of FIG. 9. Shingle 410 comprises a single tier substrate 411 and a photovoltaic assembly 440. Substrate 411 has four parallel ridges 423 and four parallel troughs 424, with the photovoltaic assembly 440 affixed to and spanning the ridges and the troughs.

Shingle 410 has an end profile 421 as seen in FIG. 35 that simulates another type of Spanish style-like shaped roofing tile with a plurality of parallel ridges that are separated by a plurality of parallel troughs. The profile of shingle 410 as seen in FIG. 35 is different than the profile of shingles 10 and 310 shown in FIGS. 22 and 33, respectively, in that while the radius of curvature of the ridges 23 and 323 are about the same as the ridges 423, the troughs 424 are flat with small rounded fillets transitioning ridges 423 and the troughs 424.

Substrate 411 has four parallel ridges 423 and five parallel troughs 424 with the first and last troughs overlapping and underlapping adjacent troughs of shingles of like character. The photovoltaic assembly 440 is affixed to and span the ridges 423 and troughs 424 of substrate 411.

The energy and power produced by the photovoltaic assembly 440 can be transmitted from conductors 44 and 46 to conductors on the inward face 419 of substrate 411 and then to jack 51.

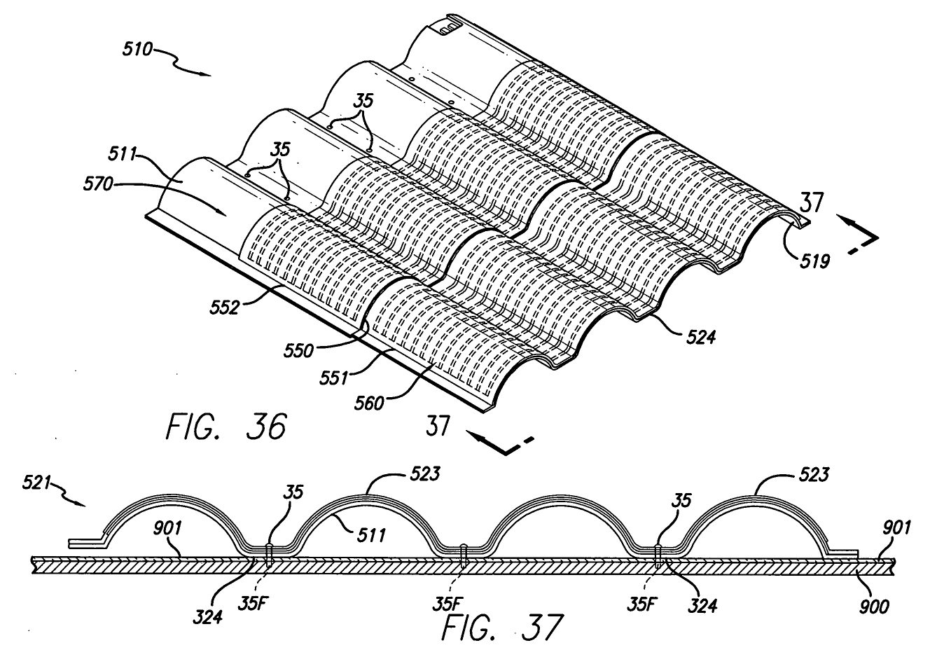

FIG. 36 is an eighth embodiment of a shingle 510 of this invention similar to the third embodiment of a shingle 110 in FIG. 24. Shingle 510 comprises substrate 511 and two photovoltaic assemblies 560 and 570. Substrate 511 has a lower tier 551 and an upper tier 552 separated by an integral riser 550.

Shingle 510 has an end profile 521 as seen in FIG. 37 that is similar to the end profile 421 in FIG. 35 except mainly for the presence of the two tiers 551 and 552 and the integral riser 550.

Substrate 511 has four parallel ridges 523 and five parallel troughs 524 with the first and last troughs overlapping and underlapping adjacent troughs of shingles of like character. The photovoltaic assemblies 560 and 570 are affixed to and span the ridges 523 and troughs 524 of tiers 551 and 552, respectively.

The energy and power produced by the photovoltaic assemblies 560 and 570 can be transmitted from conductors 44 and 46 to conductors on the inward face 519 of substrate 511 to jack 51.

FIG. 39 illustrates a method of interlocking side-to-side adjacent substrates together rather than overlapping the substrates as in FIG. 38. The right side of substrate 611a contains a snap-in prong 612a that snaps into a corresponding socket recess 613b in adjacent substrate 611b of like character to substrate 611a. Electrical connection of conductors 44 and 46 are transmitted through conductors on the inward face 619 of substrate 611, which are then connected to jack 51.

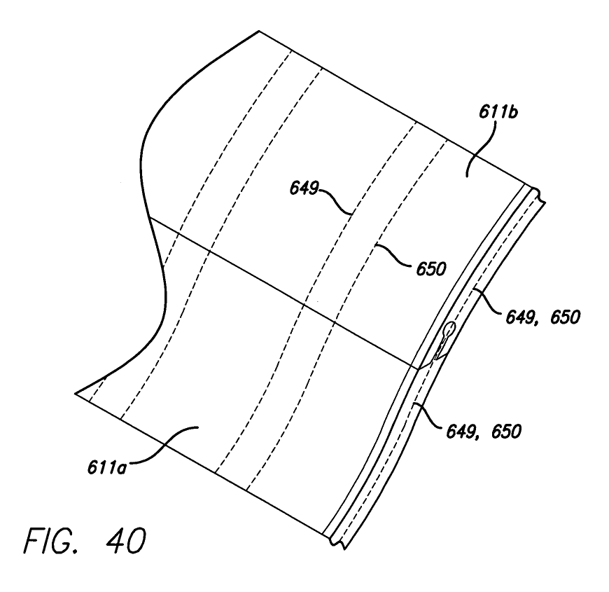

FIG. 40 illustrates yet another method of imbedding electrical conductor 649 and 650 in substrates 611a and 611b.

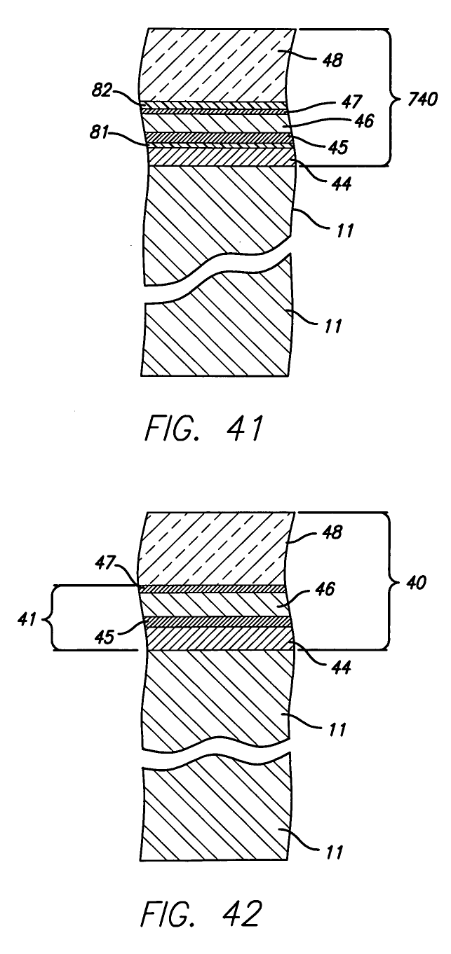

FIG. 41 illustrates the layers of another photovoltaic assembly 740 affixed to a substrate 11. Photovoltaic assembly 740 comprises a first metal conductor member 44 over the outward face of the substrate 11, a first layer of a color-imparting composition 81, a first semiconductor member 45, a second metal conductor member 46, a second semiconductor member 47, and a second layer of a color-imparting composition 82. A transparent sealer member 48 encapsulates and seals the photovoltaic cell to the substrate 11.

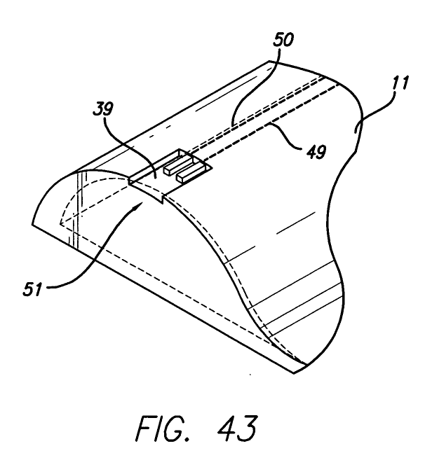

FIG. 43 illustrates an enlarged detail of electrical jack 51 contained in recess 39. One end of the jack 51 is to electrical conductors 49 and 50, and the other end of jack 51 is connected to a stringer connecting the photovoltaic cells together in a predetermined arrangement.

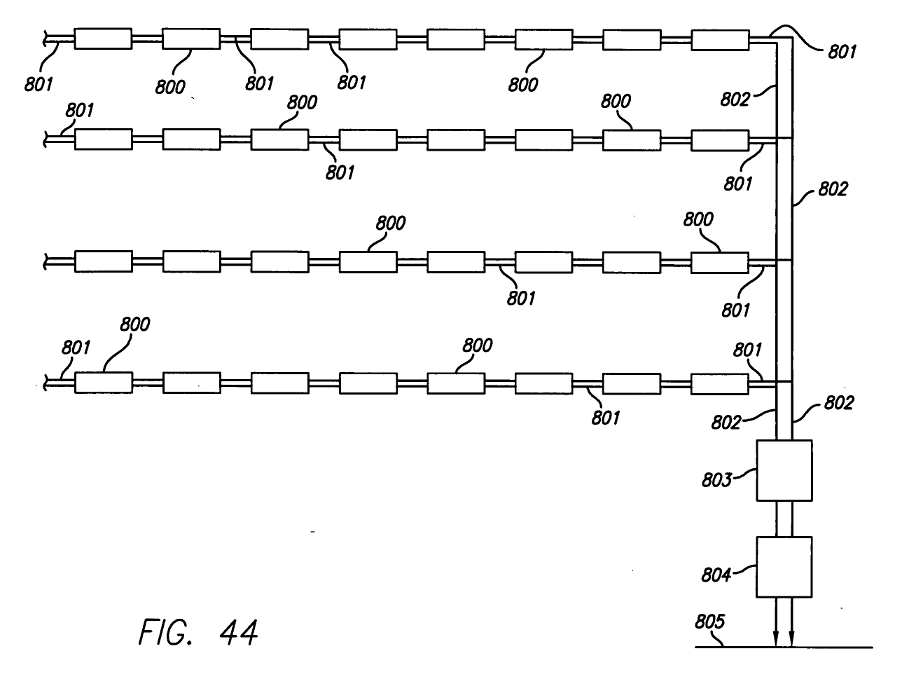

FIG. 44 is a schematic diagram of an electrical circuit for a plurality of photovoltaic shingles 800 of this invention electrically connected by stringers 801 when installed on a roof. Stringers 801 are electrically connected to a second stringer 802 that is electrically connected to a DC/AC invertor 803. Invertor 803 can be connected to a meter-measuring-recording device 804 to determine the power produced by the photovoltaic shingles before the power is fed to the utility power grid 806.

The following examples refer to a structure or roof receiving a plurality of the shingles of this invention that feature overlapped shingles as shown for example in FIGS. 45 and 46. Each of the shingles has an overlapped area and an unoverlapped area both of which are projected areas of the structure's or roof's flat surface. A large portion of unoverlapped area of each shingle will contain a photovoltaic cell or cells. The examples refer to the unoverlapped area of the shingles. The object is to have a high percentage of the unoverlapped area occupied by a photovoltaic cell or cells.

### Example 1

For a shingle having unoverlapped width of about 27.5 inches, and an unoverlapped length of about 42.0 inches and a single tier, the portion of the unoverlapped area covered by the narrow peripheral band (e.g. element 43, FIGS. 9 and 10) having a width of about 0.5 inches and without any photovoltaic cells thereunder on both the left boundary and the bottom boundary of the shingle, is about 34.5 square inches.

The result is an unoverlapped area covered by just the sealer without a photovoltaic cell thereunder of about 3.0% of the total unoverlapped area, and an unoverlapped area covered by a photovoltaic cell of about 97.0% of the total unoverlapped area.

### Example 2

For a shingle having unoverlapped width of about 27.5 inches, and an unoverlapped length of about 84.0 inches and a single tier, the portion of the unoverlapped area covered by the narrow peripheral band (e.g. element 43, FIGS. 9 and 10) having a width of about 0.5 inches and without any photovoltaic cells thereunder on both the left boundary and the bottom boundary of the shingle, is about 55.5 square inches.

The result is an unoverlapped area covered by just the sealer without a photovoltaic cell thereunder of about 2.4% of the total unoverlapped area, and an unoverlapped area covered by a photovoltaic cell of about 97.6% of the total unoverlapped area.

### Example 3

For a shingle having unoverlapped width of about 27.5 inches, and an unoverlapped length of about 42.0 inches and two tiers separated by a riser, the portion of just the unoverlapped area covered by the narrow peripheral bands (e.g. elements 163 and 173, FIGS. 24 and 25) having a width of about 0.5 inches and without any photovoltaic cells thereunder on both the left boundary, the bottom boundary, and on both sides of the riser of the shingle, is about 76.0 square inches.

The result is an unoverlapped area covered by just the sealer without a photovoltaic cell thereunder of about 6.6% of the total unoverlapped area, and an unoverlapped area covered by a photovoltaic cell of about 93.4% of the total unoverlapped area.

### Example 4

For a shingle having unoverlapped width of about 27.5 inches, and an unoverlapped length of about 84.0 inches and two tiers separated by a riser, the portion of just the unoverlapped area covered by the narrow peripheral bands (e.g. elements 163 and 173, FIGS. 24 and 25) having a width of about 0.5 inches and without any photovoltaic cells thereunder on both the left boundary, the bottom boundary, and on both sides of the riser of the shingle, is about 139 square inches.

The result is an unoverlapped area covered by just the sealer without a photovoltaic cell thereunder of about 6.0% of the total unoverlapped area, and an unoverlapped area covered by a photovoltaic cell of about 94.0% of the total unoverlapped area.

### Example 5

For a shingle having unoverlapped width of about 55 inches, and an unoverlapped length of about 42.0 inches and two tiers separated by a riser, the portion of just the unoverlapped area covered by the narrow peripheral bands (e.g. elements 163 and 173, FIGS. 24 and 25) having a width of about 0.5 inches and without any photovoltaic cells thereunder on both the left boundary, the bottom boundary, and on both sides of the riser of the shingle, is about 89.8 square inches.

The result is an unoverlapped area covered by just the sealer without a photovoltaic cell thereunder of about 3.9% of the total unoverlapped area, and an unoverlapped area covered by a photovoltaic cell of about 96.1% of the total unoverlapped area.

### Example 6

For a shingle having unoverlapped width of about 55 inches, and an unoverlapped length of about 84.0 inches and two tiers separated by a riser, the portion of just the unoverlapped area covered by the narrow peripheral bands (e.g. elements 163 and 173, FIGS. 24 and 25) having a width of about 0.5 inches and without any photovoltaic cells thereunder on both the left boundary, the bottom boundary, and on both sides of the riser of the shingle, is about 152.8 square inches.

The result is an unoverlapped area covered by just the sealer without a photovoltaic cell thereunder of about 3.3% of the total unoverlapped area, and an unoverlapped area covered by a photovoltaic cell of about 96.7% of the total unoverlapped area.

### Example 7

For a shingle having unoverlapped width of about 55.5 inches, and an unoverlapped length of about 84.0 inches and a single tier, the portion of the unoverlapped area covered by the narrow peripheral band (e.g. element 43, FIGS. 9 and 10) having a width of about 0.5 inches and without any photovoltaic cells thereunder on both the left boundary and the bottom boundary of the shingle, is about 69.3 square inches.

The result is an unoverlapped area covered by just the sealer without a photovoltaic cell thereunder of about 1.5% of the total unoverlapped area, and an unoverlapped area covered by a photovoltaic cell of about 98.5% of the total unoverlapped area.

In all of the above examples, since the actual surface area of the shingles of this invention is larger than the unoverlapped area in the above examples due to the curved surfaces of the shingles, the area of photovoltaic cells will be about 15% or more higher than the above calculated percentages, which are projected on a flat area of the structure or roof in the examples. Thus the exposed area of photovoltaic cells receiving incident solar radiation will be in most all cases greater than the total area of the flat surface of the structure or roof on which the shingles of this invention are attached.

In one embodiment of this invention the color of the shingles is customized by either adjusting the color of the substrate, or the sealer member, or addition of a color adjust layer or layers in the photovoltaic cell or a combination of the above.

The reflective properties of the photovoltaic assemblies is tailored in one embodiment of this invention so that the entire surface has an uniform appearance.

An advantage of the embodiments of the shingles of this invention having a thin film photovoltaic cells and a plastic substrate is that the shingles are lightweight and usually do not require reinforcement of the roof structure to accommodate the heavier weight of clay tile shingles or shingles with a metal substrate.

Another advantage of the various embodiments of the shingles of this invention with a thin film photovoltaic cells and a plastic substrate is that the shingles can be walked on with care without damaging the shingles and the photovoltaic cells thereof.

While the preferred embodiments of the present invention have been described, various changes, adaptations and modifications may be made thereto without departing from the spirit of the invention and the scope of the appended claims. The present disclosure and embodiments of this invention described herein are for purposes of illustration and example and modifications and improvements may be made thereto without departing from the spirit of the invention or from the scope of the claims. The claims, therefore, are to be accorded a range of equivalents commensurate in scope with the advances made over the art.

What is claimed is:

1. A photovoltaic shingle comprising:
a substrate having a left end, a right end opposite the left end, a length extending from the left end to the right end, a bottom end, a top end opposite the bottom end, a width extending from the bottom end to the top end, an outward face between the left, right, bottom and top ends, and an inward face opposite the outward face and between the left, right, bottom and top ends, the substrate also having a profile comprising a plurality of traverse parallel ridges with each ridge separated from the next ridge by a traverse parallel trough, the traverse parallel ridges and traverse parallel troughs extending the width of the substrate from the bottom end to the top end of the substrate, the outward face of the substrate having a lower area that begins at the bottom end, and an upper area that begins at the top end, the upper area of the outward face being smaller than the lower area of the outward face, wherein the lower area has a width and the upper area has a width, and wherein the width of the lower area plus the width of the upper area equals the width of the substrate, the inward face of the substrate having a lower area that begins at the bottom end, and an upper area that begins at the top end, wherein, the outward face of the upper area of the substrate is operable for providing nesting means and aligning means for an inward face of a lower area of another substrate having the profile, and wherein the inward face of the lower area of the substrate is operable for nesting with, and self aligning with, an outward face of an upper area of another substrate having the profile;
fastener receiving means located in the upper area of the outward face of the substrate proximate the top end for receiving a fastener operable for attaching the photovoltaic shingle directly to a building structure without an auxiliary support or framing structure for spacing the shingle above and away from the building structure except for an optional intermediate layer selected from the group consisting of a moisture barrier material, a thermal insulation material, and a moisture/insulating barrier material; and
a photovoltaic cell assembly affixed to, and conformed to, the outward face of the lower area of the substrate, wherein the photovoltaic cell assembly comprises a photovoltaic cell and wherein the photovoltaic cell spans at least the lower area except for a portion thereof that is intended to be overlapped by another shingle, and except for a narrow peripheral band around a periphery of the lower area of the substrate.

2. The photovoltaic shingle of claim 1, wherein the substrate is free of means for attaching the photovoltaic shingle to a support or framing structure for spacing the shingle away from the building structure except for an optional intermediate layer comprising a moisture/insulating barrier material.

3. The photovoltaic shingle of claim 1, wherein the photovoltaic cell is a thin film photovoltaic cell.

4. The photovoltaic shingle of claim 1, wherein the photovoltaic cell is a thin film cadmium-telluride photovoltaic cell.

5. The photovoltaic shingle of claim 1, wherein the photovoltaic cell covers at least about 85% of the lower area of the outward face of the substrate that is not intended to be overlapped by a photovoltaic cell of another shingle having the same profile.

6. The photovoltaic shingle of claim 1, wherein the photovoltaic cell covers at least about 90% of the lower area of the outward face of the substrate that is not intended to be overlapped by a photovoltaic cell of another shingle having the same profile.

7. The photovoltaic shingle of claim 1, wherein the photovoltaic cell assembly further comprises a plurality of tiered photovoltaic cell assemblies oriented parallel to the bottom end of the substrate, and wherein each tiered photovoltaic cell assembly has a photovoltaic cell.

8. The photovoltaic shingle of claim 1, wherein the photovoltaic cell assembly comprises anode means and cathode means for removing electrical energy from, and produced by, the photovoltaic shingle, and when the photovoltaic shingle is attached to the building structure, the anode means and the cathode means can not be seen from the outside.

9. The photovoltaic shingle of claim 1, wherein the substrate has first interlocking mechanical coupling means proximate the left end of the substrate and second interlocking mechanical coupling means proximate the right end of the substrate, wherein the first interlocking mechanical coupling means can be coupled to second interlocking mechanical coupling means of another substrate having the profile, and wherein the second interlocking mechanical coupling means can be coupled to first interlocking mechanical coupling means of another substrate having the profile.

10. The photovoltaic shingle of claim 1, wherein the photovoltaic cell assembly comprises encapsulating means for sealing the photovoltaic cell on and to the substrate so that, when the photovoltaic shingle is attached to the structure, rain will be prevented from penetrating the photovoltaic cell assembly and damaging the photovoltaic cell.

11. The photovoltaic shingle of claim 1, wherein the substrate is plastic.

12. The photovoltaic shingle of claim 1, wherein the substrate is a metal.

13. The photovoltaic shingle of claim 1, wherein the substrate has at least two tiers, and at least two ridges and at least two troughs.

14. A photovoltaic shingle comprising:
a substrate having a left end, a right end opposite the left end, a length extending from the left end to the right end, a bottom end, a top end opposite the bottom end, a width extending from the bottom end to the top end, an outward face between the left, right, bottom and top ends, and an inward face opposite the outward face and between the left, right, bottom and top ends, the substrate also having a profile comprising a plurality of traverse parallel ridges with each ridge separated from the next ridge by a traverse parallel trough, the traverse parallel ridges and traverse parallel troughs extending the width of the substrate from the bottom end to the top end of the substrate, the outward face of the substrate having a lower area that begins at the bottom end, and an upper area that begins at the top end, the upper area of the outward face being smaller than the lower area of the outward face, wherein the lower area has a width and the upper area has a width, and wherein the width of the lower area plus the width of the upper area equals the width of the substrate, the inward face of the substrate having a lower area that begins at the bottom end, and an upper area that begins at the top end; and
fastener receiving means located in the upper area of the outward face of the substrate proximate the top end for receiving a fastener operable for attaching the photovoltaic shingle directly to a building structure without an intermediary auxiliary structural support between the building structure and the substrate and without a framing structure for spacing the shingle above and away from the building structure except for an optional intermediate layer selected from the group consisting of a moisture barrier material, a thermal insulation material, and a moisture barrier/insulating barrier material, the substrate having an integral riser between a lower tier and an upper tier, wherein the outward face of the upper area of the substrate is operable for providing nesting means and aligning means for an inward face of a lower area of another substrate having the profile, wherein the inward face of the lower area of the substrate is operable for nesting with, and self aligning with, an outward face of an upper area of another substrate having the profile;
a first photovoltaic cell assembly affixed to, and conformed to, the outward face of the lower tier of the substrate, wherein the first photovoltaic cell assembly comprises a first photovoltaic cell, wherein the first photovoltaic cell spans at least the lower tier except for a portion thereof that is intended to be overlapped by another shingle, and except for a narrow peripheral band around a periphery of the lower tier of the substrate; and
a second photovoltaic cell assembly affixed to, and conformed to, the outward face of the upper tier of the substrate, wherein the second photovoltaic cell assembly comprises a second photovoltaic cell, and wherein the second photovoltaic cell spans at least the upper tier except for a portion thereof that is intended to be overlapped by another shingle, and except for a narrow peripheral band around a periphery of the lower tier of the substrate.

15. The photovoltaic shingle of claim 14, wherein a portion of the integral riser further comprises offset means for maintaining side-to-side alignment of the integral risers.

16. The photovoltaic shingle of claim 14, further comprising means for removing electrical power produced by the photovoltaic cell assemblies.

17. The photovoltaic shingle of claim 14, wherein the photovoltaic cell covers at least about 85% of the lower area of the outward face of the substrate that is not intended to be overlapped by a photovoltaic cell of another shingle having the same profile.

18. A method of producing a photovoltaic shingle having a particular color comprising:
producing a substrate having a Spanish tile-like shape with a plurality of ridges and troughs and a repetitive profile from a plastic composition;
forming a first metal conductor member on a lower area of the outer face of the substrate so that the first metal conductor member conforms to and is affixed to the substrate;
forming a first color-imparting member over the first metal conductor member so that the first color-imparting member conforms to and is affixed to the first metal conductor member;
forming a first member having a first semiconductor composition over the first color-imparting member so that the first member having the first semiconductor composition conforms to and is affixed to the first color-imparting member;
forming a second metal conductor member over the first member having the first semiconductor composition so that the second metal conductor member conforms to and is affixed to the first member having the first semiconductor composition;
forming a second member having of a second semiconductor composition over the second metal conductor member so that the second member having the second semiconductor composition conforms to and is affixed to the second metal conductor member thereby producing a photovoltaic cell; and
forming a second member having a color-imparting composition over the second member having of the second semiconductor composition thereby producing the photovoltaic shingle of the particular color.

19. The method of claim 18, further comprising forming a transparent sealer member over the second member of a color-imparting composition, the transparent sealer member effective for preventing the photovoltaic cell from being damaged by rain.

20. The method of claim 18, further comprising:
preparing a mold for producing the substrate with the Spanish tile-like shape;
producing the substrate, using the mold, from the plastic composition;
removing the substrate produced from the mold; and
using the substrate for producing the photovoltaic shingle.
